(19) United States
(12) Patent Application Publication
(10) Pub. No.: US 2004/0132308 A1
(43) Pub. Date: Jul. 8, 2004

(54) Corrosion retarding polishing slurry for the chemical mechanical polishing of copper surfaces

(75) Inventor: Yaw S. Obeng, Orlando, FL (US)

Correspondence Address: HITT GAINES P.C., P.O. BOX 832570, RICHARDSON, TX, 75083, US

(73) Assignee: PsiloQuest, Inc., Orlando, FL (US)

(21) Appl. No.: 10/685,219

(22) Filed: Oct. 14, 2003

Related U.S. Application Data
(63) Continuation-in-part of application No. 10/000,101, filed on Oct. 24, 2001.
(63) Continuation-in-part of application No. 10/241,074, filed on Sep. 11, 2002, now Pat. No. 6,706,383.
(60) Provisional application No. 60/420,371, filed on Oct. 22, 2002.

(51) Int. Cl. H01L 21/302; H01L 21/461

(52) U.S. Cl. 438/692

(57) ABSTRACT

The present invention provides a slurry for chemical mechanical polishing (CMP) a metal surface of a semiconductor substrate with a polyurethane-free thermoplastic foam polishing body. The slurry includes an abrasive particle stabilizer and an acid buffer that maintains the slurry at a pH between about 2.5 and about 4.0 during polishing of a metal surface on a semiconductor substrate. In yet another embodiment, the present invention provides a CMP polishing system. The polishing system comprises a slurry that maintains a pH between about 1 and about 6 during polishing of a metal surface on a semiconductor substrate. The system further includes a polishing pad that includes a polishing body having a polyurethane-free thermoplastic foam substrate that cooperates with the slurry to remove portions of the metal surface during said polishing.

### CROSS-REFERENCE TO RELATED APPLICATIONS

This application claims the benefit of U.S. Provisional Application No. 60/420,371 of the same title, to Yaw S. Obeng, filed on Oct. 22, 2002, and is a continuation-in-part of U.S. application Ser. No. 10/000,101, entitled, “THE ELECTIVE CHEMICAL-MECHANICAL POLISHING PROPERTIES OF A CROSS LINKED POLYMER AND SPECIFIC APPLICATIONS THEREFOR,” to Yaw S. Obeng and Edward M. Yokley, filed on Oct. 24, 2001; U.S. patent application Ser. No. 10/241,074, entitled, “A POLISHING PAD SUPPORT THAT IMPROVES POLISHING PERFORMANCE AND LONGEVITY” to Yaw S. Obeng and Peter A. Thomas, filed on Sep. 11, 2002, which in turn is a continuation-in-part of U.S. Pat. No. 6,579,604, filed on Nov. 27, 2001 and now patented, which in turn claims the benefit of U.S. Provisional Application No. 60/250,299 filed on Nov. 29, 2000, U.S. Provisional Application 60/295,315 filed on Jun. 1, 2001, and U.S. Provisional Application 60/304,375, filed on Jul. 10, 2001, all of which are commonly assigned with the present invention and incorporated herein by reference as if reproduced herein in their entirety.

### TECHNICAL FIELD OF THE INVENTION

The present invention is directed to polishing pads used for creating a smooth, ultra-flat surface on such items as glass, semiconductors, dielectric/metal composites, magnetic mass storage media and integrated circuits. More specifically, the invention is directed to a polishing slurry for metal surfaces having corrosion retarding properties.

### BACKGROUND OF THE INVENTION

Chemical-mechanical polishing (CMP) is used extensively as a planarizing technique in the manufacture of VLSI integrated circuits. It has the potential for planarizing a variety of materials in IC processing, but is used most widely for planarizing metallized layers and interlevel dielectrics on semiconductor wafers, and for planarizing substrates for shallow trench isolation. In particular, the shift towards the use of copper-based conductors presents new challenges to CMP technology.

The combination of polishing pad and slurry are important parameters defining the rate and uniformity at which a surface can be polished. CMP involves the cooperative use of a polishing pad and a slurry of chemical etchants, to rapidly remove unwanted materials, such as excess metal, from a semiconductor wafer surface with a high degree of planarity. The chemical etchants in slurries form corrosion by-products on the metal surface that are subsequently removed by the polishing pad. The corrosion by-products, however, can also corrode or alter the polishing pad surface.

In particular, for soft polishing pads having high visco-elasticity, corrosion by-products of the metal surface can interact with the polishing pad surface and detrimentally alter the pad's polishing properties such that the rates or uniformity of metal polishing are reduced. Moreover, the polishing pad may be too soft to allow removal of the corrosion by-products during the normal course of polishing, if, for example, the by-products become embedded in the pad's surface.

Accordingly, what is needed is an improved CMP slurry capable of retarding the formation of corrosion by-products on polishing pad surfaces, while not experiencing the above-mentioned problems.

### SUMMARY OF THE INVENTION

To address the above-discussed deficiencies of the prior art, the present invention provides a slurry for chemical mechanical polishing (CMP) a metal surface of a semiconductor substrate with a polyurethane-free thermoplastic foam polishing body. The slurry includes an acid buffer that maintains the slurry at a pH between about 2.5 and about 4 during polishing of a metal surface on a semiconductor substrate. The slurry further includes an abrasive particle stabilizer.

In yet another embodiment, the present invention provides a CMP system. The polishing system comprises a slurry that includes an acid buffer that maintains the slurry at a pH between about 1 and about 6 during polishing of a metal surface on a semiconductor substrate. The system also comprises a polishing pad that includes a polishing body having a polyurethane-free thermoplastic foam substrate that cooperates with the slurry to remove portions of the metal surface during the polishing.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiments as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

For a more complete understanding of the invention, reference is now made to the following descriptions taken in conjunction with the accompanying drawing, in which:

FIG. 1 illustrates a representative Pourboix phase diagram for the reaction of pure copper in an aqueous media;

FIG. 2 depicts an exemplary polishing system of the present invention;

FIG. 3 illustrates representative removal rates (RR) of copper from the surface of a wafer as function of slurry pH; and

FIG. 4 illustrates representative within wafer non-uniformity in the removal rate of copper from a wafer surface after chemical mechanical polishing using slurries with different pH.

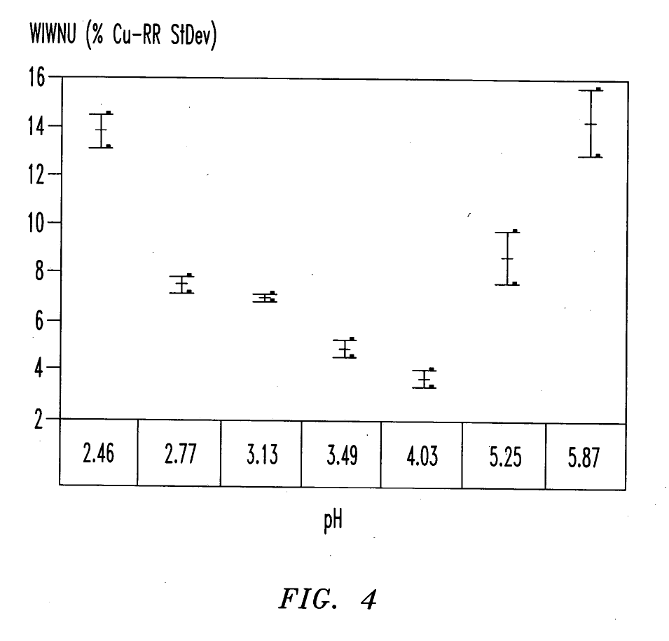

### DETAILED DESCRIPTION

The present invention benefits from the recognition that in the presence of corrosive chemical etchants in a slurry, certain corrosion by-products or polishing by-products, such as metal oxides, form on a metal surface being polished. It has presently been discovered that some by-products can be sufficiently hard so as to deter polishing by soft polishing pads. That is, the presence of hard corrosion by-products retard the ability of certain polishing pads to rapidly and uniformly polish the metal surface, as further discussed below.

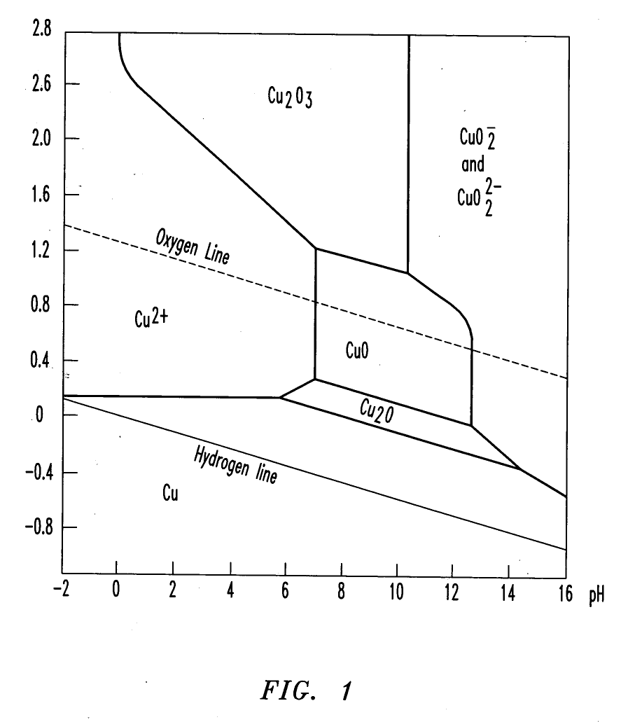

The present invention further benefits from the recognition that the metal surface being polished comprises multiple chemical species, such as illustrated in the exemplary Pourboix phase diagram shown in FIG. 1. The phase diagram in FIG. 1 illustrates various reactions and interconversions between various chemical species of pure copper in an aqueous media as a function of pH. Of course, it should be understood that these reactions would shift to lower pHs when using an aqueous media having a higher ionic strength, such as encountered in the slurry of the present invention. It is likewise understood that the presence of various slurry additives, such as oxidation agent, passivation agents, chelating agents, biocides, and abrasive particles etc . . . , further described below, will also shift the phase diagram.

The present invention discloses a polishing slurry that attenuates the production of corrosion by-products and thereby improves the polishing performance of polishing pads. In particular, acidified slurries of the present invention promote reactions that interconvert hard metal oxides to softer metal oxide that can be more efficiently removed during the normal course of polishing. Thus, such slurries result in softer corrosion by-products that can be more efficiently removed during the course of polishing.

The adjustment of slurry pH within a particular acidic range used in conjunction with polyurethane-free thermoplastic foam polishing bodies is a newly discovered result-effective variable in CMP metal polishing. That is, it was not previously recognized that the careful adjustment and maintenance of a slurry in a particular acidic pH range can result in an unexpectedly large improvement in the speed and uniformity of polishing metal surfaces on semiconductor wafer surfaces. This follows because conventional polishing pads are composed of materials, such as polyurethance, that are much harder than the polishing bodies used in the prevent invention. The hard polishing surface of the conventional polishing pads are not affected by the hard corrosion by-products generated in the presence of conventional slurries. Thus, until now, there was no need to soften the corrosion by-products on polishing surfaces by lowering the pH of the slurry as disclosed in the present invention.

One embodiment of the present invention is directed to a slurry for chemical mechanical polishing a metal surface of a semiconductor substrate with a polyurethane-free thermoplastic foam polishing body. The slurry comprises an acid buffer that maintains the slurry at a pH between about 1 and about 6 during polishing of a metal surface on a semiconductor substrate.

The slurry of the present invention can be used to polish any number of metal surfaces that are used in the semiconductor industry, such as gold, silver, tungsten, titanium, and titanium nitride. In certain preferred embodiments, however, the metal surface comprises copper or a copper alloy. The metal surface also can include metal oxides, such as copper oxides such as cuprous oxide (Cu₂O) or cupric oxide (CuO), as well as copper hydroxide (CuOH₂), and metal ions, such as cuprous (Cu⁺) and cupric (Cu²⁺) cations.

The slurry of the present invention reduces the hardness of the metal surface as compared to a hardness of the metal surface in a presence of a conventional non-acidic slurry, having a pH of about 7 or higher. As an example, within the pH range of from about 1 to about 6, it is believed that a copper surface contains a larger fraction of Cu²⁺, CuOH₂ and CuO, all of which are thought to be softer than Cu₂O. For instance, as further illustrated in the example section below, the removal rate of copper decreases from about 4000 Angstroms per minute, for a slurry pH equal to about 1, to less than about 500 Angstroms per minute, for a slurry pH equal to about 6. At a slurry pH of greater than about 6, the removal rate of copper is unacceptably low, most likely due to increased amounts of hard species, such as cuprous oxide (Cu₂O) on the metal surface as discussed previously.

In contrast, at a slurry pH of less than about 1, undesirable rapid dissolution of copper from the surface of the semiconductor substrate can occur, most likely due to a rapid conversion of Cu to soluble species such as Cu²⁺. Such dissolution is undesirable because the rate of polishing of the metal surface cannot be sufficiently controlled to provide for a uniform removal of portions of the metal surface with the desired planarity. The present invention benefits from the recognition that improved polishing can be achieved by adjusting the hardness of the metal surface to match the particular polishing properties of the polishing pad being used. Thus, in certain instances, the hardness of the metal surface is adjusted by passivating the metal surface with metal oxides that are sufficiently soft to allow controlled polishing.

As illustrated in the example section to follow, maintaining the slurry pH in a narrow pH ranges provides a surprisingly good balance between the removal rate and the within wafer uniformity of polishing. For instance, when the slurry pH is maintained between about 2.5 and about 4.0, the removal rate of copper can be maintained between about 2500 and about 1000 Angstroms per minute, while within wafer non-uniformity remains less than 14%. In other instances, it is advantageous for the slurry pH to be between about 2.7 and about 3.2. In this pH range, the removal rate of copper can remain above about 1500 Angstroms per minute while within wafer non-uniformity is less than about 8%. In yet other cases, it is desirable for the slurry pH to be between about 3.5 and about 4.0. In this pH range, the removal rate of copper may be less than about 1000 Angstroms per minute, but the within wafer non-uniformities can be less than 5%.

Any acid buffer well known to those skilled in the art can be used to maintain the slurry pH within the desired range. Preferably, the acid buffer comprised one or more compounds that have acid dissociation constants corresponding to a pKa in the range between about 0.5 and 6.0. As well understood by those skilled in the art, effective buffering occurs in the range of within about ±2 log units of the pKa value of the acid buffer. In some preferred embodiments, the pKa of the acid buffer is between about 2.5 and about 4.0, and more preferably about 3.5. Non-limiting examples of suitable acid buffers include acetic acid, phosphoric acid and periodic acid, or mixtures thereof. In some instances, however, other components in the slurry, such as the loss in effectiveness of certain passivation agents at such low pHs, can favor the use of a pH between about 4 and about 6.

Some advantageous slurry compositions include an abrasive particle stabilizer. It is preferable for the abrasive particle stabilizer to include molecules that are equivalent to the repeating units of the polymers that comprise abrasive particles in the slurry. For example, when the abrasive particles comprise colloidal silica, it is advantageous for the abrasive particle stabilizer to comprise a silicic acid and silicic salt. In other embodiments, where the abrasive particle is alumina, the abrasive particle stabilizer can comprise aluminate salts.

Such abrasive particle stabilizers retard the dissolution of the abrasive particles. This results in abrasive particles that retain their sphericity and size for longer periods during polishing. Moreover, such abrasive particle stabilizers also help prevent abrasive particles from aggregating and precipitating out of the slurry. An abrasive particle stabilizer that comprises silicic acid and silicic salt can also retard the staining and corrosion of the metal surfaces of polishing tools used in CMP.

As appreciated by those skilled in the art, colloidal silica is formed from the polymerization of monomers comprising silicic acid and silicates. In some advantageous embodiments the total concentration of silicic acid and a silicic salt, ranges between about 10⁻⁶M and about 10⁻¹M. In some embodiments, it is advantageous to set the proportion of silicic acid to silicic salt to adjust to the slurry's pH in the appropriate range. As an example, in some embodiments, a ratio of silicic acid to silicic salt is between about 100:1 and about 1:100. As appreciated by those skilled in the art, silicic acids can comprise a number of hydrated forms of silicon dioxide (SiO₂), such as tetra silicic acid (H₂Si₄O₉), meta-di silicic acid (H₂Si₂O₅), meta-tri silicic acid (H₄Si₃O₈), meta silicic acid (H₂SiO₃), ortho-tri silicic acid (H₈Si₃O₁₀), ortho-di silicic acid (H₆Si₂O₇) and ortho silicic acid (H₄SiO₄). Silicic salts can comprise similar combinations of cations and silicic anions.

Preferred embodiments of the slurry further include an abrasive particle. Any number of abrasives well known to those skilled in the art may be included in the slurry to facilitate polishing. For instances, alumina can be used as an abrasive. In some preferred embodiments, however, the abrasive comprises colloidal particles. Colloidal particles are preferred abrasives because they result in a polished metal surface with higher uniformity compared to slurries containing other types of abrasives. The uniformity of polishing can be further improved through the use of colloidal particles that are substantially spherical and have a uniform diameter. For instances, in certain preferred embodiments, the colloidal particles comprise substantially spherical colloidal silica having an average diameter of less than about 1000 microns, and more preferably less about 100 nanometers, and even more preferably a uniform diameter between about 10 and about 50 nanometers.

Preferred configurations of the slurry also include an oxidant and a passivation agent that serve to further modify the metal surface so as to facilitate polishing. Oxidants, such as hydrogen peroxide (H₂O₂), iodates (XIO₃, where X is a Group 1 cation) or bromates (XBrO₃, where X is a Group 1 cation), promote the oxidation of the metal surface, while passivation agents attenuate the extent of oxidation and reduce dissolution of the metal surface. Examples of passivation agents include benzotriazole (BTA), thioureas, thiolates, or compounds having a nitrogen atom with lone pair electrons, such as polypyridyls.

At lower pHs, however, certain passivation agents, such as BTA, lose their effectiveness because they become protonated and thus cannot effectively coordinate to the metal surface. It is advantageous therefore to use passivation agents, such as Iodine (I₂) that retain their effectiveness at pHs less than about 6. In some preferred slurries, it is desirable for the passivation agent to be generated in situ from a reaction between the metal surface and the oxidant. The in situ generation of passivation agents is advantageous when the passivation agent, such as I₂, has low solubility in the slurry medium (e.g., an aqueous medium). As an example, when the oxidant is potassium iodate (KIO₃), the reaction between the metal surface and KIO₃ results in the production of the passivation agent, I₂. Thus, in certain preferred slurries, only KIO₃, at a concentration of between about 0.1 M and about 10 M, and more preferably, between about 0.1 M and about 0.2 M, is added to the slurry.

Nevertheless, it can still be advantageous to include a second passivation agent that is not generated in situ along with the in situ generated passivation agent. It has been found that these two types of passivation agents can synergistically interact with the metal surface to better retard corrosion. As an example, when the second passivation agent is BTA, as noted above in an acid buffered slurry, BTA cannot fully coordinate to the metal surface. Consequently, there are gaps on the metal surface that are exposed to the slurry and hence corroded. However, in the presence of an in situ passivation agent, such as I₂, the combination of BTA and I₂ provide superior passivation than either of these agent alone. Though not binding the scope of the present by theory, it is thought that I₂ serves to fill in the gaps on the metal surface that are not passivated by BTA.

Certain advantageous configurations of the slurry further include a surfactant. Surfactant advantageously complex to polishing byproducts such as metals and silicates, and thereby help facilitates removal of corrosion byproducts from the metal surface being polished. In some slurries the surfactant is preferably selected from the group consisting of Triton X 100, stearic acid or mixtures thereof. In certain embodiments of the slurry, the surfactant comprise about 0.1 wt % to about 2 wt % of the slurry, and more preferably about 0.5 wt %.

Still other advantageous configurations of the slurry further include a chelating agent. Chelating agents advantageously stabilize the polishing by-products such that they do not precipitate and thereby detrimentally effect the uniformity of polishing. In some slurries the chelating agent is preferably selected from the groups consisting of polyethylene glycol, acetylacetone or mixtures thereof. In certain embodiments, the chelating agent comprise about 0.01 wt % to about 2 wt % of the slurry, and more preferably about 1 wt %.

Yet other preferred slurry compositions further include a biocide to prevent fungus or other organisms from growing in the slurry. One preferred biocide comprises ammonium bifluoride in a concentration range of about 0.01 w % to about 1 wt % and more preferably about 0.5 wt %. Of course other biocides, well known to those skilled in the art, could be used.

The slurry could be packaged as a single component or as a multiple component system that is mixed at the point of use. For example, the slurry could include a first component package, such as acid buffer, abrasive particle stablizer, abrasive particle, plus surfactant, biocide, and chelating agent. The slurry could further include a second component package, comprising an oxidant plus passivation agent precursor, such as KIO₃, plus acid buffers, chelating agents and second passivation agent.

FIG. 1 illustrates another embodiment of the present invention, a CMP polishing system 100. The polishing system 100 comprises a slurry 110 and a polishing pad 120. The slurry 110, as described above, comprises an acid buffer that maintains the slurry 110 at a pH between about 1 and about 6 during polishing of a metal surface 130 on a semiconductor substrate 140. Any of the above described slurry configurations can be used in the system 100 to polish any number of metal surfaces 130 as described above. The polishing pad 120 includes a polishing body 150 comprising a polyurethane-free thermoplastic foam substrate that cooperates with the slurry 110 to remove portions of the metal surface 130 during polishing.

As noted above, the slurry 110 decreases the proportion of hard metal oxides, such as Cu₂O and promotes the presence of softer metal oxides, hydroxides and metal, such as CuO, CuOH₂ and Cu, respectively. For instance, in embodiments when the metal surface 130 comprises copper and copper oxides, the slurry 110 maintain a higher ratio of copper to copper oxides as compared to an analogous ratio of copper to copper oxides in a non-acidic slurry. The slurry 130 thus cooperates with the polishing body 150 by facilitating the pad's ability to polish the metal surface 130.

The slurry 110 can be used with a polishing pad 120 having a polishing body 150 that comprises a polyurethane-free thermoplastic foam substrate. In particular it is advantageous for the thermoplastic foam substrate of the polishing body 150 to having a surface comprises concave cells 160. In preferred embodiments, a polishing agent 170 coats an interior surface of the concave cells 160.

Skived thermoplastic foam substrates provide an excellent surface 160 for receiving a uniform coating of the polishing agent 170. The term skiving as used herein means any process to a cut away a thin layer of the surface of the substrate so as to expose concave cells within the thermoplastic foam substrate. The center of the concave cells 175 are thought to serve as a nucleating point for coating because the surface energy of the cell at the center is lowest. It is believed that the initiation of coating at this location facilitates the uniform coverage of the interior surface of the concave cells 160 with the polishing agent 170, thereby facilitating the polishing performance of the pad 120.

The term cell as used herein, refers to any volume defined by a membrane within the substrate occupied by air, or other gases used as blowing agents, defining a substantially concave cell 175 formed upon skiving of the substrate. The concave cell 175 need not have smooth or curved walls. Rather, the concave cells 175 may have irregular shapes and sizes. Several factors, such as the composition of the substrate and the procedure used to prepare the foam substrate, may affect the shape and size of the concave cells 175.

The polishing body 150 can comprise a polyurethane-free thermoplastic foam substrate such as that described in U.S. patent application Ser. No. 10/000,101, to Yaw S. Obeng and Edward M. Yokley, and U.S. patent application Ser. No. 10/241,074, to Yaw S. Obeng and Peter A. Thomas. Examples include cross-linked polyolefins, such as polyethylene, polypropylene, and combinations thereof. Other examples include polyvinyl esters.

In certain preferred embodiments, the thermoplastic foam substrate is comprises a closed-cell foam of crosslinked homopolymer or copolymers. Examples of closed-cell foam crosslinked homopolymers comprising polyethylene (PE) include: Volara™ and Volextra™ from Voltek (Lawrence, Mass.); Aliplast™, from JMS Plastics Supply, Inc. (Neptune, N.J.); or Senflex T-Cell™ (Rogers Corp., Rogers, Conn.). Examples of closed-cell foams of crosslinked copolymers comprising polyethylene and ethylene vinyl acetate (EVA) include: Volara™ and Volextra™ (from Voltek Corp.); Senflex EVA™ (from Rogers Corp.); and J-foam™ (from JMS Plastics JMS Plastics Supply, Inc.).

In certain advantageous embodiments, the closed-cell foam is comprised of a blend of crosslinked ethylene vinyl acetate copolymer and a low density polyethylene copolymer (i.e., preferably between about 0.1 and about 0.3 gm/cc). In yet other advantageous embodiments, the blend has a ethylene vinyl acetate:polyethylene weight ratio between about 1:9 and about 9:1. In certain preferred embodiments, the blend comprises EVA ranging from about 5 to about 45 wt %, preferably about 6 to about 25 wt % and more preferably about 12 to about 24 wt %. Such blends are thought to be conducive to the desirable production of concave cells having a small size as further discussed below. In still more preferred embodiments, the blend has a ethylene vinyl acetate:polyethylene weight ratio between about 0.6:9.4 and about 1.8:8.2. In even more preferred embodiments, the blend has a ethylene vinyl acetate:polyethylene weight ratio between about 0.6:9.4 and about 1.2:8.8.

In yet other advantageous embodiments, the thermoplastic foam substrate of the polishing body 150 can be characterized as having at least about 85 wt % Xylene insoluble material. The process for measuring Xylene insoluble materials is well-known to those of ordinary skill in the art. Such processes may involve, for example, digestion of the blend in Xylene for 24 hours at 120° C. followed by drying and comparing the weight of the residual insoluble material to the predigestion material.

In another aspect, the thermoplastic foam substrate of the polishing body 150 has cells 178 formed throughout the substrate. In certain exemplary embodiments, the cells 178 are substantially spheroidal. In other embodiments, however, the size of the cells 178 are such that, on skiving the substrate, the open concave cells 175 at the surface of the substrate 160 have an average size between about 100 microns and 600 microns. The average size of the concave cells 175 ranges from about 100 to about 350 microns, preferably about 100 to about 250 microns and more preferably about 115 to about 200 microns. Cell size may be determined using standard protocols, developed and published by the American Society for Testing and Materials (West Conshohocken, Pa.), for example, such as ASTM D3576, incorporated herein by reference.

Perferably, where the shape of the cell is substantially spherical, cell size is approximately equal to the mean cell diameter. In those embodiments comprising EVA copolymer, for example, cell diameter is a function of the EVA content of co-polymer bend, as disclosed by Perez et al. J. Appl. Polymer Sci, vol. 68, 1998 pp 1237-1244, incorporated by reference herein. As disclosed by Perez et al. bulk density and cell density are inversely related. Thus, in other preferred embodiments, the density of concave cells at the surface of the substrate ranges between 2.5 and about 100 cells/mm², and more preferably, between about 60 and 100 cells/mm². Cell density may be determined, for example, from visual inspection of microscopic images of the substrate's surface.

The thermoplastic foam substrate of the polishing body 150 may further comprise up to about 25 wt % of an inorganic filler material. The inorganic filler may comprise any Group I, Group II or Transition Metal well known to those of ordinary skill in the art to impart desirable translucence, color or lubricant properties to the foam substrate. For example, the inorganic filler may be selected from the group consisting of Talc, Titanium Oxides, Calcium Silicates, Calcium Carbonate, Magnesium Silicates, and Zinc salts. The thermoplastic foam substrate may comprise about 17 wt % Talc. In other embodiments, the filler comprises silica (about 20 to about 25 wt %), zinc oxides (about 1 wt %), stearic acid (about 1 wt %), and other additives and pigments (up to about 2%) well known to those of ordinary skill in the art. Other conventional filler materials, such as those revealed in U.S. Pat. Nos. 6,425,816 and 6,425,803, incorporated by reference herein, are also within the scope of the present invention.

The thermoplastic foam substrate of the polishing body 150 also desirably has certain mechanical properties to facilitate polishing. Specifically, the thermoplastic foam substrate must be capable of deforming during polishing to an extent sufficient to allow the polishing agent 170 coating the interior surface of the concave cells 160 to facilitate polishing. Preferably, the thermoplastic foam substrate of the polishing body 150 has a hardness of between about 30 shore A and about 80 shore A, and more preferably between about 30 shore A and about 40 shore A. The thermoplastic foam substrate of the polishing body 150 may have a Tensile Elongation between about 100% and about 800%. For example, Tensile Elongation may be between about 100% and about 450%. In yet other embodiments, Tensile Elongation is between about 600% and about 800%. Tensile Elongation may be determined using standard protocols, such as ASTM D3575, incorporated herein by reference.

The polishing agent 170 may comprise one or more ceramic compounds or one or more organic polymers, resulting from the grafting of the secondary reactants on the substrate's surface, as disclosed in U.S. Pat. No. 6,579,604 or U.S. Pat. No. 6,596,388, both to Obeng and Yokley, and both incorporated herein by reference. The ceramic polishing agents 170 may comprise an inorganic metal oxide resulting when an oxygen-containing organometallic compound is used as the secondary reactant to produce a grafted surface. For example, the secondary plasma mixture may include a transition metal such as titanium, manganese, or tantalum. However, any metal element capable of forming a volatile organometallic compound, such as metal ester contain one or more oxygen atoms, and capable of being grafted to the polymer surface is suitable. Silicon may also be employed as the metal portion of the organometallic secondary plasma mixture. In such embodiments, the organic portion of the organometallic reagent may be an ester, acetate, or alkoxy fragment. In advantageous embodiments, the polishing agent is selected from a group of ceramics consisting of Silicon Oxides and Titanium Oxides, such as Silicon Dioxide and Titanium Dioxide; Tetraethoxy Silane Polymer; and Titanium Alkoxide Polymer.

Numerous other secondary reactant may be used to produce the ceramic polishing agent 170, however. The secondary plasma reactant may include ozone, alkoxy silanes, water, ammonia, alcohols, mineral sprits or hydrogen peroxide. For example, the secondary plasma reactant may be composed of titanium esters, tantalum alkoxides, including tantalum alkoxides wherein the alkoxide portion has 1-5 carbon atoms; manganese acetate solution in water; manganese alkoxide dissolved in mineral spirits; manganese acetate; manganese acetylacetonate; aluminum alkoxides; alkoxy aluminates; aluminum oxides; zirconium alkoxides, wherein the alkoxide has 1-5 carbon atoms; alkoxy zirconates; magnesium acetate; and magnesium acetylacetonate. Other embodiments are also contemplated for the secondary plasma reactant, for example, alkoxy silanes and ozone, alkoxy silanes and ammonia, titanium esters and water, titanium esters and alcohols, or titanium esters and ozone.

Alternatively, the polishing agent 170 may comprise an organic polymer when organic compounds are used as the secondary plasma reactant. Examples of such secondary reactants include: allyl alcohols; allyl amines; allyl alkylamines, where the alkyl groups contain 1-8 carbon atoms; allyl ethers; secondary amines, where the alkyl groups contain 1-8 carbon; alkyl hydrazines, where the alkyl groups contain 1-8 carbon atoms; acrylic acid; methacrylic acid; acrylic acid esters containing 1-8 carbon atoms; methacrylic esters containing 1-8 carbon atoms; or vinyl pyridine, and vinyl esters, for example, vinyl acetate. The polishing agent 170 may be selected from a group of polymers consisting of polyalcohols and polyamines.

The coating of polishing agents 170 may advantageously alter the physical properties of the substrate comprising the polishing pad 120. For example, the substrate, after being coated with an organic polymer polishing agent, has peak Tan Delta at least about 40° C. lower than the uncoated thermoplastic foam substrate. In other preferred embodiments, the peak loss modulus of the organic polymer coated substrate is at least about 10° C. lower than for the uncoated substrate. The peak Tan Delta and peak Loss Modulus may be determined using techniques, such as Dynamic Mechanical Analysis, well known to those of ordinary skill in the art.

In an alternative embodiment, the thermoplastic foam substrate of the polishing body 150 is coupled to a stiff backing material 180. A stiff backing 180 limits the compressibility and elongation of the foam during polishing, which in turn, reduce erosion and dishing effects during metal polishing via CMP. The stiff backing material 180 may, in certain aspects, comprise a high density polyethylene (i.e., greater than about 0.98 gm/cc), and more preferably, a condensed high density polyethylene. The coupling can be achieved via chemical bonding using a conventional adhesive 185, such as epoxy or other materials well known to those skilled in the art. In other embodiments, however, coupling is achieved via extrusion coating of the molten backing material 180 onto the foam 150. In still other embodiments the backing 180 is thermally welded to the foam 150.

Advantageous configurations of the CMP system 100 further include a mechanically driven carrier head 190 and a polishing platen 195, wherein the polishing pad 120 is attached to the polishing platen 195. The carrier head 190 is positionable against the polishing platen 195 to impart a polishing force against the polishing platen 195. Additional embodiments of the system 100 can include a conventional carrier ring 200 and adhesive 205 to couple the substrate 140 to the carrier head 190.

The polishing pad 120 in cooperation with the slurry 110 is preferably capable of polishing a copper metal surface 130 on a wafer substrate 140 at a removal rate of at least about 2000 Angstroms/minute using a down force of about 20 kPa, a table speed between about 25 rpm and a carrier speed of about 40 rpm. Preferably, the removal rate has a within wafer non-uniformity of less than about 14%. In still other preferred embodiments, the removal rate of copper is at least about 1000 Angstroms/minute with a within wafer non-uniformity of less than about 4%.

Having described the present invention, it is believed that the same will become even more apparent by reference to the following experiments. It will be appreciated that the experiments are presented solely for the purpose of illustration and should not be construed as limiting the invention. For example, although the experiments described below may be carried out in a laboratory setting, one skilled in the art could adjust specific numbers, dimensions and quantities up to appropriate values for a full-scale plant setting.

### EXPERIMENTS

Experiments were conducted to the measure the metal polishing properties of polishing pads in the presence of slurries of the present invention and in comparison to various conventional slurries.

Stock slurry solutions were prepared by mixing two slurry packages together. The first slurry package included an abrasive such as colloidal silica “DAN Ascend 300” (Product Number Ascend Cu300, from DuPont Air Products, Carlsbad Calif.), or alumina in “MSW2000” (Product Number MSW2000 from Rodel, Newark Del.). The second slurry package included an oxidant such as hydrogen peroxide and acid buffer such as glacial acidic acid. Alternatively, the second slurry package included a periodic acid-containing commercial oxidation package, such as MicroPlanar® CMP3550 (EKC Dupont, Danville Calif.). As well understood by those skilled in the art, periodic acid may comprise ortho (H₅IO₆) or para (HIO₄) forms, or mixtures thereof. Prior to polishing, the first and second slurry packages were mixed together so as to provide a slurry at the desired pH, as further described below.

The polishing pads comprised a polishing body laminated to a backing material comprising an about 0.03 inch thick condensed HDPE layer (hardness about 90 shore A). Coupling between the polishing body and the backing material was achieved via extrusion coating of the molten HDPE on a prefabricated roll of thermoplastic foam. To affix the polishing pad to a polishing table, the backing material was backed with a pressure sensitive adhesive (3M product number 9731). The polishing body comprised a thermoplastic foam substrate comprised 0.070″ EVA-PE foam (Volextra™ from Voltek) having a hardness of about 30 shore A. The thermoplastic foam substrate comprised ˜12 weight percent talc, ˜18 weight percent EVA and balance PE. About 9 percent of the thermoplastic foam substrate's volume comprised cells. After skiving, the polishing body was about 64 mil thick and had a surface comprising concave cells and a polishing agent comprising an about 500 micron thick layer of amorphous SIO₂ coating an interior surface of the concave cells via plasma enhanced CVD as further described below. The polishing body was laser scored to afford slurry channels.

The thermoplastic foam substrate was skived with a commercial cutting blade (Model number D5100 K1, from Fecken-Kirfel, Aachen, Germany) and then manually cleaned with an aqueous/isopropyl alcohol solution. To coat the substrate with polishing agent comprising silicon dioxide, the skived substrate was placed in the reaction chamber of a conventional commercial Radio Frequency Glow Discharge (RFGD) plasma reactor having a temperature controlled electrode configuration (Model PE-2; Advanced Energy Systems, Medford, N.Y.).

The plasma treatment of the substrate was commenced by introducing the primary plasma reactant, Argon, for about 30 to about 120 seconds, depending on sample size and rotation speed, within the reaction chamber maintained at about 350 mTorr. The electrode temperature was maintained at about 30° C., and a RF operating power of about 100 to about 2500 Watts was used, depending on the sample and reaction chamber size.

Subsequently, the secondary reactant was introduced for either 10 or 30 minutes at 0.10 SLM and consisted of the silicon dioxide metal ester precursor, tetraethoxysilane (TEOS), mixed with He or Ar gas. The amount of precursor in the gas stream was governed by the vapor pressure (BP) of the secondary reactant monomer at the monomer reservoir temperature (MRT; 90±10° C.). Similar procedures were used to prepare polishing bodies coated with a polishing agent comprising TiO₂, using a secondary plasma reactant containing tetraorthotitinate.

Copper polishing properties were assessed using a commercial polisher IPEC 472 (Product No. EP0222 from Ebara Technologies, Sacramento, Calif., now owned by Novellus Systems Inc., Calif.). No preconditioning was performed on the pad prior to commencing the experiment. Unless otherwise noted, the removal rate of copper polishing was assessed using a down force of about 20 kPa (˜3 psi), back side pressure of about 6.9 kPa (˜1 psi) a table speed of about 25 rpm, a carrier speed of about 40 rpm and slurry flow rate of about 125 ml/min. About 10,000 Angstrom thick wafers having electroplated with an about 8,000 Angstrom thick copper layer were used for test polishing.

The within wafer nonuniformity (WIWNU) of copper removal across the wafer's surface was assessed using the same polishing apparatus and conditions. Contour plots of the copper surfaces after polishing were measured electrically by measuring sheet resistance at 49 points distributed radially across the wafer. The average post-polishing depths of copper removed across the wafer, the standard deviation of the depth removed and the percent standard deviation of the depth removed (WIWNU) were calculated from the 49 measured of sheet resistance.

The polishing properties of the polishing pads having SiO₂-coated polishing bodies prepared as described above, were examined in several different slurry environments. In one series of experiments, the DAN Ascend 300 abrasive package was mixed with a second oxidant package containing H₂O₂, to provide a slurry having a final H₂O₂ concentration of either 5% or 10% (vol/vol) and a pH of ˜7.6. DAN Ascend 300 includes BTA. The DAN Ascend 300 abrasive package was also mixed with sufficient glacial acetic acid to provide a slurry having a pH of about 4.0. A second commercial abrasive package, MSW2000, includes potassium iodide (KI) and is provided at a pH of about pH 2.0.

Exemplary copper removal rates (RR) using these slurries are presented in TABLE 1. The results in TABLE 1 illustrate a dramatic increase in the polishing rates for slurries having acidic pHs and, in particular, as the pH of the slurry is decreased below about 4, with even higher rates obtained and a pH equal to about 2. The observation of haze on the polished surface at higher pHs indicates the presence of undesirable corrosion by-products on the metal surface post-polishing.

TABLE 1

| | | Cu RR | |
|---|---|---|---|
| | | (Angstroms/ | |
| SLURRY | pH | min) | Observations |
| DAN Ascend ® Cu- | 7.6 | ˜200 | No obvious haze/ |
| 300 + 5% H₂O₂ | | | corrosion |
| DAN Ascend ® Cu- | 7.6 | ˜100 | No obvious haze/ |
| 300 + 10% H₂O₂ | | | corrosion |
| DAN Ascend Cu 300 + Glacial | 4.0 | 2300 | Haze/Corrosion |
| Acetic | | | |
| MSW2000 | 2.0 | 5000 | No obvious haze/ |
| | | | corrosion |

To further explore the relationship between slurry pH and copper polishing, another series of slurries were investigated using the same type of polishing pad as used in the experiments described in TABLE 1. A fixed volume (˜500 ml) of the DAN Ascend 300 abrasive package was titrated with variable amounts of the commercial oxidant package, EKC-3510, to provide slurries of the present invention ranging in pH from about 1 to 6.

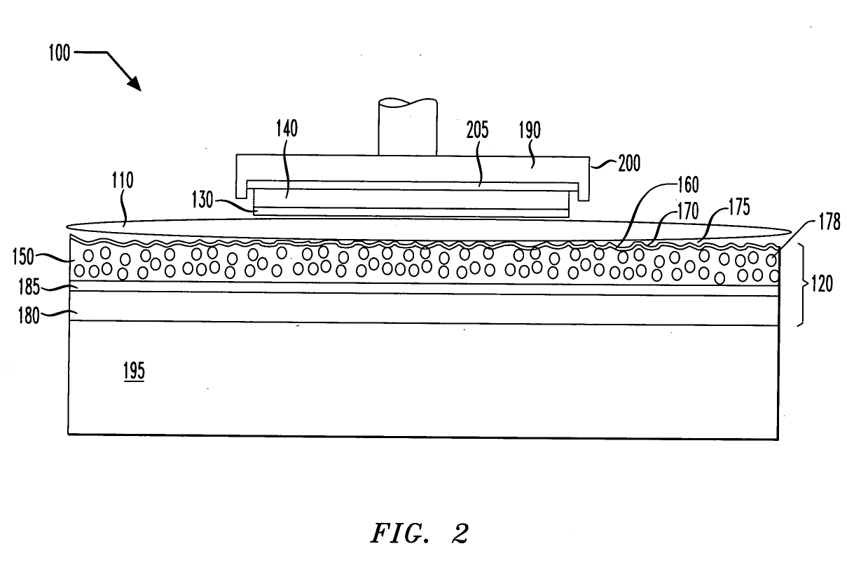

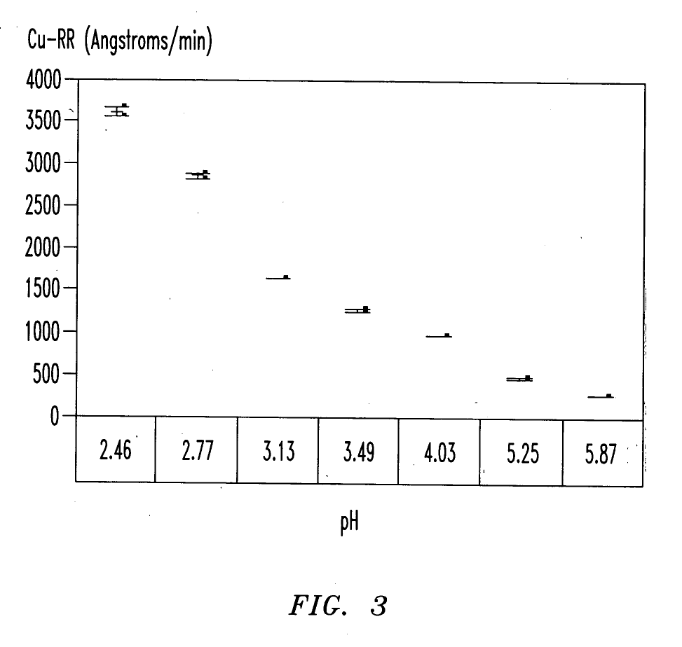

FIGS. 2 and 3 illustrate, respectively, exemplary copper removal rates (RR) and within wafer nonuniformity of copper removal (WIWNU) as a function of slurry pH. The removal rate of copper decreases from about 4000 Angstroms per minute for a slurry pH of about 1, to less than about 500 Angstroms per minute for a slurry pH equal to about 6 pH. In a narrower pH range between about 2.5 and about 4.0, there was a surprizingly good combination of high removal rate and uniformity. For instance, the WIWNU had a minimum of less than less than 14% and removal rate between about 2500 and about 1000 Angstroms per minute. Even narrower pH ranges provide a number of unexpected advantages. For slurry pHs between about 2.7 and about 3.2, the removal rate was above about 1500 Angstroms per minute while within WIWNU was less than about 8%. For slurry pHs between about 3.5 and about 4.0 the removal rate was less than about 1000 Angstroms per minute, with a WIWNU of less than 5%.

Although the present invention has been described in detail, those skilled in the art should understand that they can make various changes, substitutions and alterations herein without departing from the scope of the invention.

What is claimed is:

1. A slurry for chemical mechanical polishing (CMP) a metal surface of a semiconductor substrate with a polyurethane free thermoplastic foam polishing body, comprising,
an acid buffer that maintains said slurry at a pH between about 2.5 and about 4.0 during polishing of a metal surface on a semiconductor substrate; and
an abrasive particle stabilizer.

2. The slurry as recited in claim 1, wherein said pH is between about 2.7 and about 3.2.

3. The slurry as recited in claim 1, wherein said pH is between about 3.5 and about 4.0.

4. The slurry as recited in claim 1, wherein said abrasive particle stabilizer comprises molecules that are equivalent to repeating units of polymers comprising abrasive particles in said slurry.

5. The slurry as recited in claim 4, wherein said abrasive particles comprise colloidal silica particles and said abrasive particle stabilizer comprises silicic acid and silicic salt.

6. The slurry as recited in claim 5, wherein a ratio of said silicic acid to said silicic salt is between about 100:1 and 1:100.

7. The slurry as recited in claim 4, wherein said abrasive particles comprise alumina and said abrasive particle stabilizer comprises aluminate salts.

8. The slurry as recited in claim 1, further including an oxidant and a passivation agent.

9. The slurry as recited in claim 8, wherein said passivation agent is generated in situ from a reaction between said metal surface and said oxidant.

10. The slurry as recited in claim 9, wherein said oxidant is potassium iodate (KIO₃) said passivation agent is iodine (I₂) and said metal surface includes copper.

11. The slurry as recited in claim 9, further including a second passivation agent that is not generated in situ wherein said passivation agent and said second passivation agent synergistically interact with said metal surface to retard corrosion of said metal surface.

12. A chemical mechanical polishing (CMP) system comprising,
a slurry comprising an acid buffer that maintains said slurry at a pH between about 1 and about 6 during polishing of a metal surface on a semiconductor substrate; and
a polishing pad that includes a polishing body having a polyurethane-free thermoplastic foam substrate that cooperates with said slurry to remove portions of said metal surface during said polishing.

13. The CMP system as recited in claim 12, wherein said metal surface comprises copper and copper oxides, and wherein said slurry maintain a higher ratio of said copper to said copper oxides as compared to said ratio in a non-acidic slurry.

14. The CMP system as recited in claim 12, wherein said polishing body further includes said thermoplastic foam substrate having a surface comprised of concave cells and a polishing agent coating an interior surface of said concave cells.

15. The CMP system as recited in claim 12, wherein said thermoplastic foam substrate comprises a closed-cell foam of crosslinked homopolymer or compolymers.

16. The CMP system as recited in claim 12, wherein said closed-cell foam is comprised of a blend of cross-linked ethylene vinyl acetate copolymer and a low or medium density polyethylene copolymer having a ethylene vinyl acetate:polyethylene ratio between about 1:9 and about 9:1.

17. The CMP system as recited in claim 12, wherein said polishing body has a hardness of between about 30 shore A and about 80 shore A.

18. The CMP system as recited in claim 12, wherein said polishing pad is capable of polishing said metal surface at a removal rate of at least about 2000 Angstroms/minute using a down force of about 20 kPa, a table speed between about 25 rpm and a carrier speed of about 40 rpm.

19. The CMP system as recited in claim 18, wherein said removal rate has a within wafer non-uniformity of less than about 14%.

20. The CMP system as recited in claim 18, wherein said removal rate is at least about 1000 Angstroms/minute and said removal rate has a within wafer non-uniformity of less than about 4%.
